(19) United States
(12) Patent Application Publication
(10) Pub. No.: US 2011/0090488 A1
(43) Pub. Date: Apr. 21, 2011

(54) Sensing And Control Device

(76) Inventors: Jens Christian Folkmar Andersen, Fredericia (DK); Karsten Schack Madsen, Odense C (DK); Kenneth Rehhoff, Odense C (DK)

(21) Appl. No.: 12/996,113

(22) PCT Filed: Jun. 4, 2009
(86) PCT No.: PCT/DK09/00132

§ 371 Date: Dec. 3, 2010

(30) Foreign Application Priority Data
Jun. 5, 2008 (DK) PA 2008 00779

(51) Int. Cl. G01J 1/00; G01R 33/02; H05B 37/02; F16K 37/00

(52) U.S. Cl. 356/213; 324/244; 315/152; 137/553

(57) ABSTRACT

An actuator rod position indication device is described, where a unit having a separate enclosing housing on one surface of said housing has mounted a magnetic field sensor, such that a magnet provided on an actuator rod's free end will be moved substantially linearly closer to and further from said sensor during operation of the actuator, where the sensor detects the magnetic field strength between the magnet on the actuator rod and the sensor and uses this information as input in a processor, comprising a storage, in which storage pre-defined activation values are stored, such that when the input corresponds to one of the stored values, an output specific to that value is generated.

### FIELD OF THE INVENTION

The present invention relates to a sensing and control device for indicating an actuator rod position as well as a valve construction incorporating such a device.

### BACKGROUND OF THE INVENTION

In the art there are a number of automatic valves which are supplied with indication and control units such that the unit may both indicate by a visible signal, for example by means of light or an acoustic signal, the condition of the valve as well as be provided with means for supplying feed-back to a central control unit.

Examples of such sensing and control devices are available from the Alfa Laval Corporation under the brand names Think Top or Indi Top.

Most of these devices are very reliable and accurate and are extremely useful for indicating complex valve movements, for example indicating the valve's closure member's exact position. These valves are very complex and are therefore often relatively expensive to buy and also to install in that they need to be calibrated very precisely in order to provide the correct position. Furthermore they often contain a number of sensors, which together provides the feed back necessary to operate the devices. Often, it is only desirable to know whether the valve is open or closed or in a position in between.

A number of prior art constructions provide such valve indication means, see for example EP 0740097 B1, wherein an angular precision indicator is disclosed where the position indicator comprises two mutually rotatable parts enclosed in a transparent housing. As the valve stem rotates, one of the movable parts has a notch lodged in a groove provided in the other member such that the rotation will cause the first member to move relatively to the second member. During this movement the first member which in one end position will indicate “closed” through the transparent window will move the second member upwards thereby covering the sign “closed” by the second member on which surface “open” may be indicated such that to a viewer it is clear whether or not the valve is in its open position or its closed position. Furthermore, it may also be possible to deduct a position in between the open and closed positions, but this indication is uncertain in that there is not grading of the scale between open and closed.

Another example is illustrated with reference to U.S. Pat. No. 5,223,822 in which an indication member may be rotated relative to the valve stem, such that the rotatable member may be brought into a position in relation to a window where the position of the valve may be indicated also by “closed”, “off” or “open”.

A comparable structure is known from U.S. Pat. No. 6,242,909. This construction, however, is more complicated in that it in addition to mechanical means for indicating also comprises an electronic circuitry whereby it is possible to supply feedback to a control system.

The device according to U.S. Pat. No. 6,242,909 has a higher degree of accuracy but also a very high degree of complicity in its construction.

The prior art devices mentioned above all rely on the fact that they are mechanically connected to the valve stem/actuator such that movement of the actuator causes rotation whereby an indication device will display either “open” or “closed” depending on its relative position.

This in turn implies that there is a physical connection between the valve construction and the valve position indicator. This may cause two drawbacks, one of which is the fact that it is very difficult to fit the indicating device to the valve construction afterwards, i.e. if the valve construction is not manufactured with the indicating device as an integrated part of the device. Furthermore, mechanical couplings tend to wear which may give rise to failure such that uncertainties relating to the actual position of the valve closure member due to failure in the connection between the valve stein/actuator and the indicating device may give rise to the indicating device providing the wrong information.

### OBJECT OF THE INVENTION

It is therefore an object of the present invention to provide an actuator rod position indication device which reliably provides indication of the actuator's position and thereby the valve closure member's position in the valve construction.

### DESCRIPTION OF THE INVENTION

The present invention consequently discloses an actuator rod position indication device, where a unit having a separate enclosing housing on one surface of said housing has mounted a magnetic field sensor, such that a magnet provided on an actuator rod's free end will be moved substantially linearly closer to and further from said sensor during operation of the actuator, where the sensor detects the magnetic field strength between the magnet on the actuator rod and the sensor and uses this information as input in a processor, comprising a storage, in which storage pre-defined activation values are stored, such that when the input corresponds to one of the stored values, an output specific to that value is generated.

By relying on the strength of a magnetic field created between the sensor and a magnet arranged at the actuator rod's free end, there is no physical connection between the sensor and thereby the indicating device and the valve construction as such. This provides two advantages, namely that it is relatively easy to retrofit the actuator rod position indication device to existing valve constructions of the type having an actuator rod moving the valve closure member such that the actuator rod's position is an indication of the valve's position whether it is opened, closed or any position in between.

A further advantage with the present invention is the fact that only one sensor is used. In prior art devices where indication of open and closed is achieved this is facilitated by two independent sensors. For further position indications in between “open” or “closed” additional sensors are necessary. Each sensor has to be calibrated independently, such that reliable feed back is obtained. By only having a single sensor, it is only necessary to read the magnetic field strength in the open and closed positions or any desired position in between, which thereafter will provide the desired feed-back.

In comparison to prior art devices the present invention does not influence or come into contact with the valve construction and as such may be considered a completely independent device which may be built onto any valve. Furthermore, the reliability of the indication device is quite high in that the measurement of the magnetic field strength is a well-known and well documented technique such that reliable sensors, electronic circuits etc., are available in order to implement the invention. Furthermore, as the system is not mechanical it is possible to provide a cheque routine for the electronic circuitry such that the indication device automatically will generate an error indication if for some reason detection of the magnetic field should give rise to such an error indication.

By having an actuator moving linearly closer to or away from the sensor the behaviour of the magnetic field will be more or less homogenous such that the change in the magnetic field will follow a curve which may be well defined and documented. In this manner it is possible to store pre-defined activation values, for example if the valve seat is in its “closed” position, the actuating rod will be in its position farthest away from the sensor such that the magnetic field is at its weakest. By introducing an activation value corresponding to the weakest magnetic field, the activation value may trigger the indication device to indicate “closed”.

In a further advantageous embodiment of the invention the sensor processor storage and necessary connections are enclosed in said housing, where the housing is moisture and gas proof.

Often industrial valves are arranged in relatively hostile environments such that the valves shall be constructed to withstand high or low temperatures, high or low relative humidity, the exposure to aggressive cleaning compounds, steam or high pressure cleaning etc., and for these reasons the indication device may in this embodiment be completely enclosed such that the influence from the environment does not enter into the indication device as such. This may be achieved by having a sealed housing, for example made from a material not influencing the magnetic field and where for example an overpressure inside the housing is present relative to the ambient pressure whereby temperature changes, ambient pressure changes and the like will not influence the centre and the associated circuitry. This is important in that in the aggressive environment where valve constructions are often placed this environment may have a detrimental effect on especially the printed circuit board and its components and as such diminish the life expectancy of a device. By providing a completely sealed housing the life expectancy and the reliability of the device is increased.

In a further advantageous embodiment at least values corresponding to the actuator rod's [magnetic member's] closest and farthest away positions are stored in the storage and have two distinct outputs relating to these positions.

This is the simplest embodiment where only the open and closed position of the valve is registered and generates an output. For valves where only these two indications are interesting, i.e. valves incorporated in systems having relatively simple functions these indications will be fulfilling. For example in dairy installations it is very important to know that for example the valve separating cleaning fluids from dairy products is in a closed position when dairy products are being treated in the system, and that it is in the “open” position when the pipe system is to be cleaned etc.

In a still further advantageous embodiment the housing comprises light sources, whereby each generated output activates separate light sources or a combination of different light sources.

In the simple embodiment mentioned above indicating the “open” and “closed” position may for example be achieved by simply activating two separate light sources, one being red for close, one being green for open. In addition, different light sources may also be provided, for example a flashing orange light source may indicate an error, or in embodiments where data relating to the number of cycles the valve is open and closed and/or number of operating hours are stored in the storage, a special light may come up after a predefined number of cycles or working hours in order indicate that it is time to carry out preventive maintenance of the valve construction or the like.

In a still further advantageous embodiment a distinct colour light is activated for each of the actuator rod's closest and farthest away positions, and optionally that means are provided for activating both distinct light sources at the same time, but with different light intensities, such that the movement of the rod may be indicated by the shift in light intensities.

In this embodiment in addition to indicating clearly the fully open and fully closed positions, the positions in between “open” and “closed” may for example be indicated by different light intensities such that as soon as the valve opens a little bit, the red light will be dominating, but a slightly green light may also be detected. As the valve opens progressively, the green light will intensify and at the same time the red light will dampen such that the valve's movement from “closed” towards “open” may be indicated by the variants in light intensity from the two light sources. It should be borne in mind that the light indications red and green are only for illustrative purposes and any type of light, colour or otherwise may be implemented in order to indicate the position of the valve. In this connection it should further be noted that the progressive change from for example red light towards green light will not be a precise indication for the current position of the valve closure member, but will only give an inspector or operator a rough idea of the valve closure's position.

The indication may also, due to the provision of suitable communicating means, either by wire or wireless, be transmitted to a remote location, where the inspector or operator may monitor the installation.

In a still further advantageous embodiment sensor means for sensing the ambient brightness is provided, where said sensor means inputs information to the processor, whereby the light intensity relative to the ambient light is substantially constant. This embodiment provides the feature that should the light conditions surrounding the valve change, the light intensity of the indication means will change accordingly, such that e.g. in bright sunlight/daylight the light intensity of the indication means on the indication device will shine brightly, whereas during night operations or in the dark only dimmed light will be shining in order to indicate the position of the actuation rod.

It is also foreseen with the present invention that the sensor may calibrate itself in the end positions. By initially moving from open to closed and registering the positions as initial “open” resp. “closed” values/positions, the corresponding magnetic field strengths will be stored as pre-defined values, which will be the basis for further operation of the device.

The invention is also directed to a valve construction comprising a valve seat and a closure member, where said closure member is connected to an actuation rod, where movement of said rod determines the closure members position between an open and a closed position relative to said valve seat, and where an actuator rod position indication device according to any of the preceding claims, is provided.

### DESCRIPTION OF THE DRAWING

The invention will now be explained with reference to the accompanying drawing wherein

FIG. 1 illustrates a valve actuator housing on which is mounted an actuator rod position indication device;

FIG. 2 illustrates a valve actuator housing on which a basic lid, having no sensor is mounted;

FIG. 3 illustrates a schematic cross section through a valve actuator housing on which is mounted an actuator rod position indication device;

FIG. 4 illustrates a valve actuator housing on the surface of which is provided a window for indicating the current position of the valve.

### DETAILED DESCRIPTION OF THE INVENTION

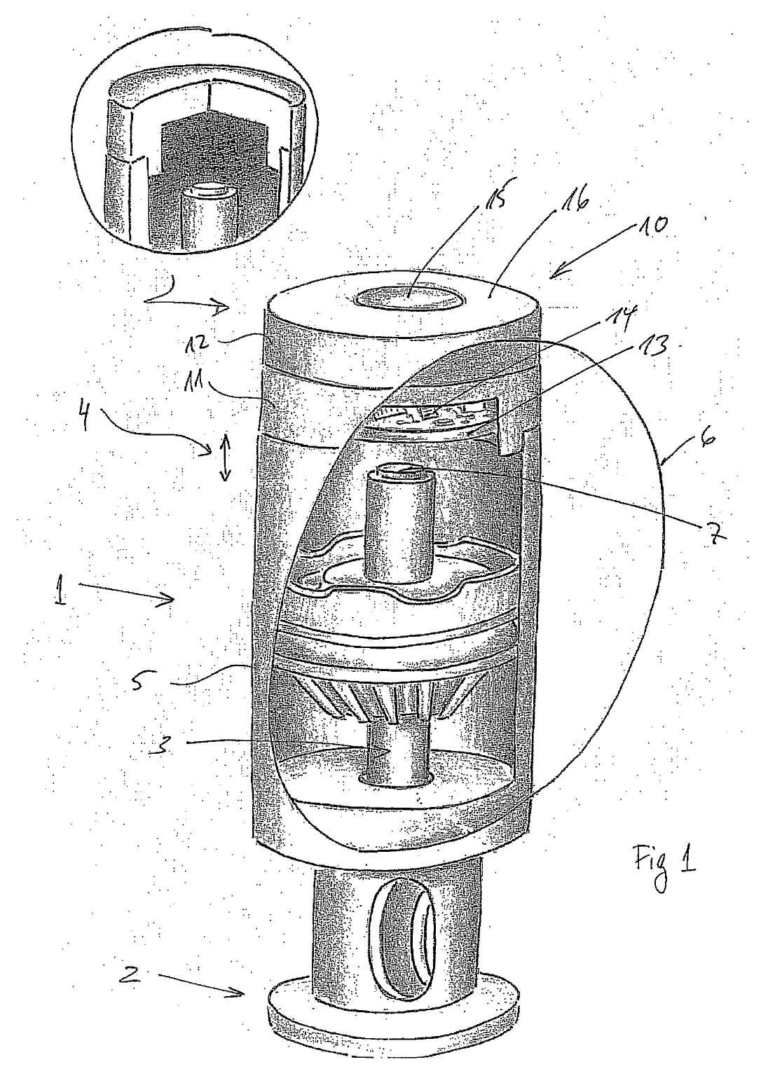

In FIG. 1 is illustrated a valve top 1 which is suitable to be mounted onto a valve construction by means of a flange 2. The valve top 1 comprises actuating means (not illustrated) for activating a valve rod 3 linearly up and down as indicated by the arrow 4. The actuator rod 3 is coupled to the valve closure member such that by moving the valve rod upwards the valve closure member may be moved from a closed position to a position in which the valve is open, i.e. it is possible to move a liquid across the valve structure and vice versa by moving the valve rod 3 downwards, the valve closure member may be brought into contact with the valve seat thereby closing off communication in a pipeline.

The actuator rod, as well as the means for activating the rod are enclosed in a housing 5 which for illustrative purposes has a cut-off section illustrated by the circle 6. In the interior of the housing 5 the means for moving the actuator 3 are placed as well as the actuator. The actuator rod 3 is provided with a magnet 7 in the free end of the actuator rod.

The housing 5 is provided with a housing 10 for the actuator rod position indication device. In this embodiment the housing 10 comprises a base part 11 which is adapted to be mounted on the housing 5 of the valve top 1 for example by being screwed onto the housing 5, and furthermore a transparent upper part 12 is provided in the indication device housing 10. Inside the housing 10 is provided a PCB 13 on which the necessary electronic components 14 are mounted. One of the necessary components is a sensor detecting the magnetic field between the magnet 7 and the magnetic sensor provided on the PCB 13.

The PCB may also functions as the bottom part of the indication device housing 10 or may be mounted on a separate bottom member and is sealed against the lower part 11 such that ingress of gas, moisture and the like is avoided.

As the magnet 7 fastened in the free end of the actuator rod 3 is moved up and down in relation to the actuator rod's movement the magnetic field strength between the magnet 7 and the sensor arranged in the PCB 13 will vary. By means of appropriate programming in the microprocessors the relative position of the valve rod 3 will be able to be determined, depending on the field strength of the magnetic field between the magnet 7 and the sensor arranged in the PCB 13.

Depending of the manner in which the processor has been programmed relating to pre-defined activation values, the upper part 12 of the indication device housing 10 may be illumination, in this example in two different colours depending on the position of the actuator rod 3. For example in the open position, the central part 15 of the upper part 12 of the indication device housing 10 may be illuminated in a green colour indicating that the valve is open and operable. In the closed position the ring part 16 of the upper part of the indication device housing 10 may be illuminated in a red colour indicating that the valve is closed.

In this manner it is very easy and fast for an operator to detect/register the condition of this specific valve, simply by visually inspecting the top part of the valve housing. It should be clear that by positioning the light emitting means on the PCB, for example in the shape of LEDs, the constructor or designer is completely free to design any light pattern being emitted from the translucent or transparent part of the indicator device housing 10.

In order to compensate for the ambient light conditions, a light intensity sensor (registering the Lux) may be arranged on the PCB such that the intensity with which the light sources arranged on the PCB are activated is according to the ambient light conditions may be regulated. In order that the light sensors detecting the ambient light are not influenced by the illumination from the LEDs placed on the PCB, the LEDs may be turned on and off very quickly such that it is possible for the light sensor to measure the ambient light in the off-periods. By alternating the on-off for the LEDs very quickly, it does appear to a viewer that there is a constant light once the alternation reaches a certain frequency.

The housing 10 is furthermore kept under a slightly elevated pressure relative to the ambient pressure or to the pressure which may occur in the immediate surroundings of the valve housing such that ingress of gas, moisture and the like will effectively be avoided. In this manner it is possible to provide a substantially maintenance free actuator rod indication device in that it has no moving parts and has no tear and wear due to its function. The sensor detecting the strength of the magnetic field may be a so-called Hall element.

In FIG. 2 is illustrated a basis module where the top of the actuator housing 5 is illustrated. The top is prepared for mounting of an actuator rod indication device according to the present invention, but is in this embodiment provided with a base cap 6 without any of the inventive features of the present invention.

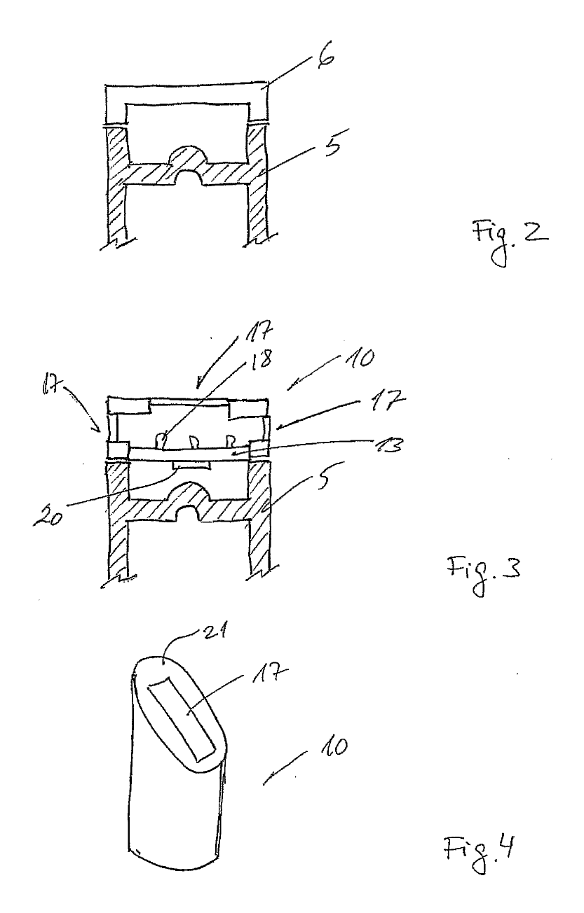

Turning to FIG. 3 the same housing 5 is mounted with an inventive actuator rod indication device 10 according to the present invention. In this context it should be noted that the device 10 may be fastened to the valve top housing 5 in any appropriate manner such as for example by being screwed on as indicated in FIG. 1 or by an adhesive connection between the two housings 5, 10. Wires supplying power and input/output are not illustrated for clarity reasons.

The housing 10 is provided with a number of translucent/transparent sections 17. Furthermore, at number of LEDs indicated by 18 are mounted on a PCB 13, which serves as bottom in the housing 10 by being sealingly connected to the rest of the housing. In the PCB is furthermore mounted a Hall element 20, which detects the magnetic field strength.

In FIG. 4 is illustrated a different design where the top of the housing 10 has a slanting surface 21 in which a transparent/translucent window 17 is provided. By arranging the LEDs in an array parallel to the longitudinal direction of the window 17, it may be possible to indicate various stages of the closing/opening procedure of the valve, i.e. the different positions of the actuating rod 3 by illuminating one or more of the LEDs placed behind the window 17.

The invention is not limited to the embodiments described above and shown on the drawings, but can be supplemented and modified in any manner within the scope of the invention as defined by the enclosed claims.

1. A sensing and control device, where said sensing and control device comprises a processor, and a storage, and further where a unit having a separate enclosing housing on one surface of said housing has mounted a magnetic field sensor, such that a magnet provided on an actuator rod's free end will be moved substantially linearly closer to or further away from said sensor during operation of the actuator wherein the sensor, processor, storage and necessary connections are enclosed in said housing, where the housing is moisture and gas proof, where the sensor detects the magnetic field strength between the magnet on the actuator rod and the sensor and uses this information as input in the processor, comprising a storage, in which storage pre-defined activation values are stored, such that when the input corresponds to one of the stored values, an output specific to that value is generated.

2. (canceled)

3. The sensing and control device according to claim 1 wherein at least values corresponding to the actuator rod's (magnetic member's) closest and furthest away positions are stored in the storage and has two distinct outputs relating to these positions.

4. The sensing and control device according to claim 1 or claim 3 wherein the housing comprises light sources, whereby each generated output activates separate light sources or a combination of different light sources.

5. The sensing and control device according to claim 3 wherein a distinct colour light is activated for each of the actuator rod's closest and furthest away positions, and optionally means are provided for activating both distinct light sources at the same time, but with different light intensities, such that the movement of the rod may be indicated by the shift in light intensities.

6. The sensing and control device according to claim 4 wherein sensor means for sensing the ambient brightness are provided, where said sensor means inputs information to the processor, whereby the light intensity relative to the ambient light is substantially constant.

7. The sensing and control device according to claim 1 wherein when initially activated the actuator moves to both extreme positions corresponding to strongest magnetic field strength and weakest magnetic field strength, where these field strengths are used as reference pre-defined values.

8. A valve construction comprising a valve seat and a closure member, where said closure member is connected to an actuation rod, where movement of said rod determines the closure member's position between an open and a closed position relative to said valve seat, and where an actuator rod position indication device according to claim 1 is provided.
